(19) United States
(12) Patent Application Publication
(10) Pub. No.: US 2025/0364419 A1
(43) Pub. Date: Nov. 27, 2025

(54) SEMICONDUCTOR DEVICES

(71) Applicant: Samsung Electronics Co., Ltd., Suwon-si (KR)

(72) Inventors: Doyoon Moh, Suwon-si (KR); Donghoon Kwon, Suwon-si (KR)

(21) Appl. No.: 19/023,729

(22) Filed: Jan. 16, 2025

(30) Foreign Application Priority Data
May 22, 2024 (KR) 10-2024-0066328

(51) Int. Cl. H01L 23/535; H01L 21/768; H01L 23/532

(52) U.S. Cl. CPC H01L 23/535; H01L 21/7685; H01L 21/76895; H01L 23/53252

(57) ABSTRACT

A semiconductor device includes an interconnection line including a first portion and a second portion; a via on the first portion of the interconnection line; a conductive barrier layer between a lower surface of the via and an upper surface of the first portion of the interconnection line; and an interlayer insulating layer in contact with side surfaces of the interconnection line, the via, and the conductive barrier layer and covering the second portion of the interconnection line

### CROSS-REFERENCE TO RELATED APPLICATION(S)

This application claims benefit of priority to Korean Patent Application No. 10-2024-0066328 filed on May 22, 2024, in the Korean Intellectual Property Office, the disclosure of which is incorporated herein by reference in its entirety.

### BACKGROUND

Example embodiments of the present disclosure relate to a semiconductor device including a via and an interconnection line.

As demands for high performance, high speed, and/or multifunctionality in a semiconductor device have increased, integration density of a semiconductor device has increased. With the trend for higher integration density of a semiconductor device, a size of a transistor has been reduced. As the size of a transistor has been reduced, research to ensure electrical stability of a semiconductor device has been conducted.

### SUMMARY

An example embodiment of the present disclosure is to provide a semiconductor device having improved reliability.

According to an example embodiment of the present disclosure, a semiconductor device includes a first contact plug having a first upper surface and a second contact plug having a second upper surface disposed at a vertical level different from a vertical level of the first upper surface; a first conductor structure disposed on the first contact plug and connected to an upper surface of the first contact plug; a second conductor structure disposed on the second contact plug and connected to an upper surface of the second contact plug; and an interlayer insulating layer on side surfaces of the first and second conductor structures, wherein the first and second contact plugs include portions disposed at the same vertical level as one another, wherein the first conductor structure includes a first interconnection line connected to the first upper surface of the first contact plug; a first via on the first interconnection line; and a first barrier layer between the first interconnection line and the first via, wherein the second conductor structure includes a second interconnection line connected to the second upper surface of the second contact plug; a second via on the second interconnection line; and a second barrier layer between the second interconnection line and the second via, wherein the first interconnection line, the first via, and the first barrier layer have first side surfaces which are aligned, wherein the second interconnection line, the second via, and the second barrier layer have second side surfaces which are aligned, and wherein the interlayer insulating layer is in contact with the first side surfaces of the first interconnection line, the first via, and the first barrier layer, and the second side surfaces of the second interconnection line, the second via, and the second barrier layer.

According to an example embodiment of the present disclosure, a semiconductor device includes an interconnection line including a first portion and a second portion; a via on the first portion of the interconnection line; a conductive barrier layer between a lower surface of the via and an upper surface of the first portion of the interconnection line; and an interlayer insulating layer in contact with side surfaces of the interconnection line, the via, and the conductive barrier layer and covering the second portion of the interconnection line.

According to an example embodiment of the present disclosure, a semiconductor device includes a first contact plug having a first upper surface and a second contact plug having a second upper surface disposed at a vertical level different than a vertical level of the first upper surface; a first conductor structure disposed on the first contact plug and connected to an upper surface of the first contact plug; a second conductor structure disposed on the second contact plug and connected to an upper surface of the second contact plug; and an interlayer insulating layer on side surfaces of the first and second conductor structures, wherein the first and second contact plugs include portions disposed at the same vertical level as one another, wherein the first conductor structure includes a first interconnection line connected to the first upper surface of the first contact plug; and a first via on the first interconnection line, wherein the second conductor structure includes a second interconnection line connected to the second upper surface of the second contact plug and having an upper surface lower than an upper surface of the first interconnection line; a second via on the second interconnection line; and a barrier layer disposed between the second interconnection line and the second via, wherein a vertical thickness of the first via is different from a vertical thickness of the second via.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a cross-sectional diagram illustrating a portion of a semiconductor device according to example embodiments of the present disclosure;

FIG. 1B is an enlarged diagram illustrating region A of the semiconductor device illustrated in FIG. 1A;

FIGS. 1C and 1D are enlarged diagrams illustrating region A of the semiconductor device illustrated in FIG. 1A;

FIGS. 2, 3, 4, 5, 6, 7, 8, 9, and 10 are cross-sectional diagrams illustrating a portion of a semiconductor device according to other example embodiments of the present disclosure;

FIG. 11A is a plan diagram illustrating a portion of a semiconductor device according to an example embodiment of the present disclosure;

FIG. 11B is a cross-sectional diagram illustrating a portion of the semiconductor device in FIG. 11A, taken along lines I-I′ and II-II′;

FIGS. 12A, 12B, 12C, 12D, 12E, and 12F are diagrams illustrating a method of manufacturing the semiconductor device of FIG. 4 according to example embodiments of the present disclosure;

FIGS. 13A, 13B, and 13C are diagrams illustrating a method of manufacturing the semiconductor device of FIG. 4 according to example embodiments of the present disclosure; and

FIGS. 14A, 14B, 14C, 14D, 14E, 14F, and 14G diagrams illustrating a method of manufacturing the semiconductor device in FIG. 8 according to example embodiments of the present disclosure.

### DETAILED DESCRIPTION

Hereinafter, embodiments of the present disclosure will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes. Furthermore, when components of a circuit are described as connected, it will be understood that such a connection may be an electrical connection.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

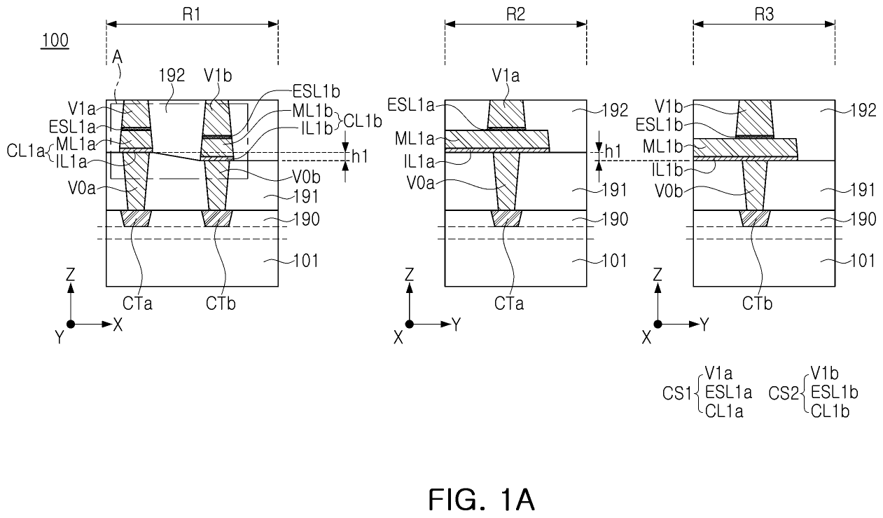

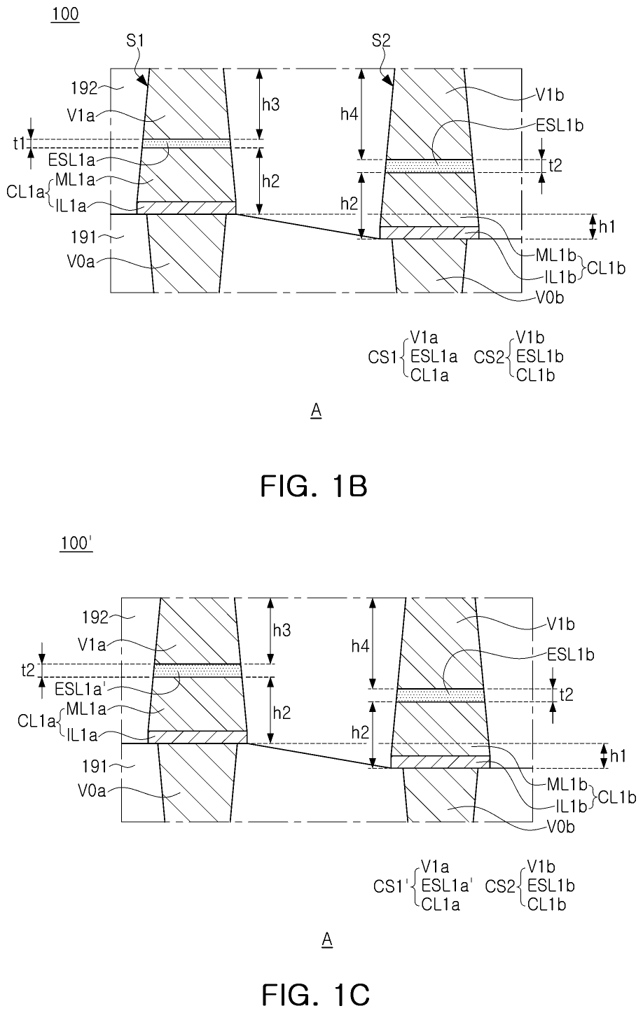

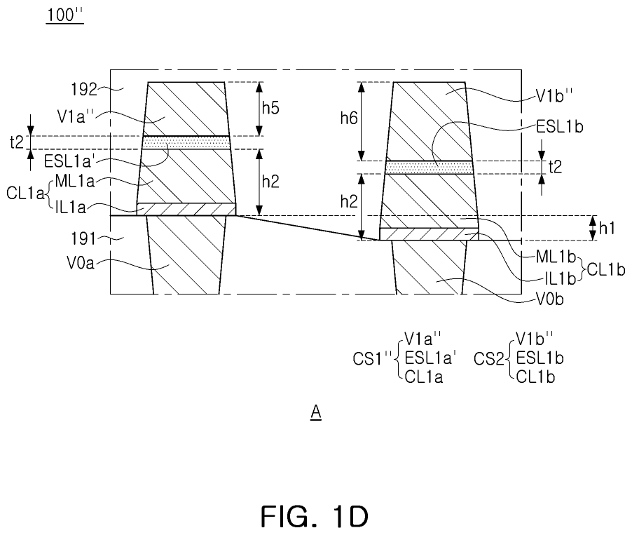

FIG. 1A is a cross-sectional diagram illustrating a portion of a semiconductor device according to example embodiments. FIGS. 1B to 1D are enlarged diagrams illustrating region A of the semiconductor device illustrated in FIG. 1A. For ease of description, FIG. 1A illustrates only a portion of the semiconductor device.

In FIG. 1A, the region R1 may represent a cross-sectional view perpendicular to the second direction (Y-direction) of the region of the first and second conductor structures CS1 and CS2 taken in the first direction (X-direction), the region R2 may represent a cross-sectional perpendicular to the first direction (X-direction) view of the region of the first conductor structure CS1 taken in the second direction (Y-direction), and the region R3 may represent a cross-sectional view perpendicular to the second direction (Y-direction) of the region of the second conductor structure CS2 taken in the second direction (Y-direction).

Referring to FIGS. 1A and 1B, the semiconductor device 100 may include a substrate 101, first and second contact structures CTa and CTb, first and second contact plugs V0a and V0b on the first and second contact structures CTa and CTb, a first conductor structure CS1 on the first contact plug V0a, and a second conductor structure CS2 on the second contact plug V0b.

The semiconductor device 100 may further include a first lower insulating structure 190 surrounding side surfaces of the first and second contact structures CTa and CTb and exposing upper surfaces of the first and second contact structures CTa and CTb, a second lower insulating structure 191 surrounding side surfaces of the first and second contact plugs V0a and V0b, and an interlayer insulating layer 192 (e.g., a first interlayer insulating layer) surrounding side surfaces of the first and second conductor structures CS1 and CS2. In an example, the first and second lower insulating structures 190 and 191 and the interlayer insulating layer 192 may include at least one of silicon oxide or silicon nitride. In example embodiments, the interlayer insulating layer 192 may be referred to as the first interlayer insulating layer 192.

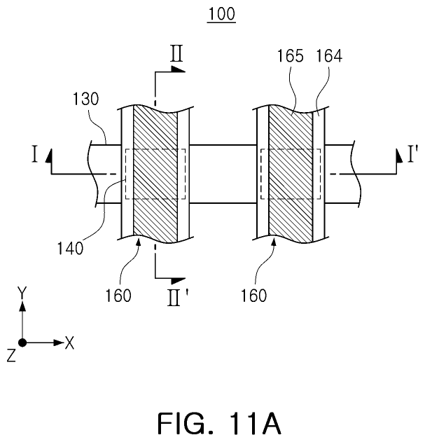

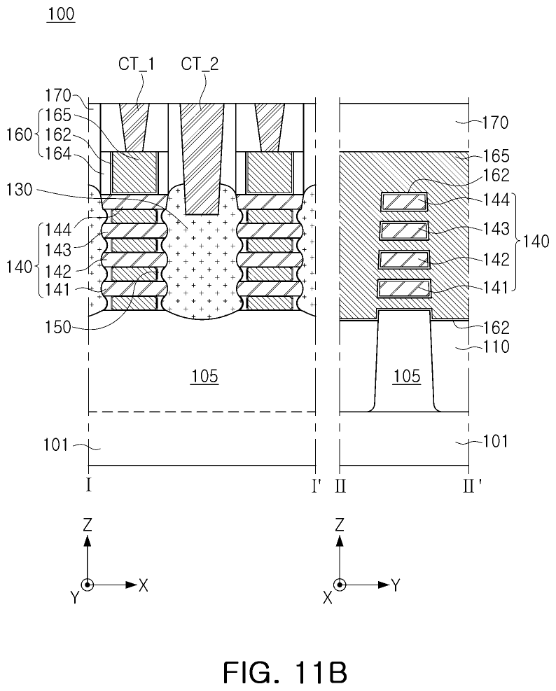

The substrate 101 may include a semiconductor material, such as a group IV semiconductor, a group III-V compound semiconductor, or a group II-IV compound semiconductor. A well region and a device isolation layer may be provided and/or formed on the substrate 101 with reference to FIGS. 11A and 11B. In an example, an N-type field effect transistor nFET and/or a P-type field effect transistor pFET may be provided and/or formed on the substrate 101.

The first lower insulating structure 190 may be formed on the substrate 101. The first and second contact structures CTa and CTb may be provided and/or formed in the first lower insulating structure 190. In an example, an upper surface of the first lower insulating structure 190 may be disposed at the same level as upper surfaces of the first and second contact structures CTa and CTb (e.g., the distance between a reference plane such as a base surface of the substrate 101 and each of the upper surfaces may be the same and the distance may be a vertical distance). The term level when describing a surface may refer to a relative vertical level of the surface relative to a common base surface such as a reference plane such as a base surface of the substrate 101.

The first and second contact structures CTa and CTb may be electrically connected to a transistor (not illustrated) provided on the substrate 101. In an example, the first contact structure CTa and the second contact structure CTb may each have an upper surface and a lower surface disposed at the same level as each other. However, an example embodiment thereof is not limited thereto, and the first contact structure CTa and the second contact structure CTb may each have an upper surface disposed at different levels as each other. For example, the upper surface of the first contact structure CTa may be disposed at a level higher than a level of the upper surface of the second contact structure CTb. In an example, the first and second contact structures CTa and CTb may each have inclined side surfaces such that a width thereof decreases toward the substrate 101. However, an example embodiment thereof is not limited thereto. In an example, the first and second contact structures CTa and CTb may include, for example, a metal material such as tungsten (W), cobalt (Co), molybdenum (Mo), copper (Cu), ruthenium (Ru), or aluminum (Al). In an example, the first and second contact structures CTa and CTb may be spaced apart from each other in the horizontal direction. The first and second contact structures CTa and CTb may be provided and/or formed in the same process. However, an example embodiment thereof is not limited thereto, and the first contact structure CTa and the second contact structure CTb may be provided and/or formed in order.

The first contact plug V0a may be disposed on the first contact structure CTa, and the second contact plug V0b may be disposed on the second contact structure CTb. In an example, the first contact plug V0a may be in contact with the upper surface of the first contact structure CTa. The second contact plug V0b may be in contact with the upper surface of the second contact structure CTb. In an example, widths of lower regions of the first and second contact plugs V0a and V0b may be smaller than widths of upper regions of the first and second contact structures CTa and CTb, respectively. However, an example embodiment thereof is not limited thereto. In an example embodiment, the first and second contact plugs V0a and V0b may have inclined side surfaces such that widths may decrease toward the substrate 101. However, an example embodiment thereof is not limited thereto.

The first contact plug V0a and the second contact plug V0b may each include portions disposed at the same level. In an example, the lower surface of the first contact plug V0a may be disposed at the same level as the lower surface of the second contact plug V0b. However, an example embodiment thereof is not limited thereto. In another example, when the upper surface of the first contact structure CTa is disposed at a level different from a level of the upper surface of the second contact structure CTb, the lower surface of the first contact plug V0a may be disposed at a level different from a level of the lower surface of the second contact plug V0b.

The upper surface of the first contact plug V0a may be disposed at a level different from a level of the upper surface of the second contact plug V0b. For example, the upper surface of the first contact plug V0a may be disposed at a level higher than a level of the upper surface of the second contact plug V0b. However, an example embodiment thereof is not limited thereto, and the upper surface of the first contact plug V0a may be disposed at a level lower than a level of the upper surface of the second contact plug V0b. In example embodiments, for ease of description, the example embodiment in which the upper surface of the first contact plug V0a is disposed at a level higher than a level of the upper surface of the second contact plug V0b will be described.

As the upper surface of the first contact plug V0a is disposed at a level different from a level of the upper surface of the second contact plug V0b, a step difference h1 may be formed between the upper surface of the first contact plug Va and the upper surface of the second contact plug V0b. The size of the step difference h1 between the first and second contact plugs V0a and V0b may be about 1-2 nm. However, an example embodiment thereof is not limited thereto, and the step difference h1 between the first and second contact plugs V0a and V0b may be 2 nm or more.

The first conductor structure CS1 may be disposed on the first contact plug V0a. In an example, the first conductor structure CS1 may be in contact with the upper surface of the first contact plug V0a. The second conductor structure CS2 may be in contact with the upper surface of the second contact plug V0b. In an example, as the upper surface of the first contact plug V0a and the upper surface of the second contact plug V0b are disposed at different levels, the lower surface of the first conductor structure CS1 and the lower surface of the second conductor structure CS2 may be disposed at different levels. In an example, the lower surface of the first conductor structure CS1 may be disposed at a level higher than a level of the lower surface of the second conductor structure CS2.

The first and second conductor structures CS1 and CS2 may have inclined side surfaces such that widths thereof may increase downwardly in the vertical direction (Z-direction).

The first conductor structure CS1 may include a first interconnection line CL1a, first via V1a, and a first barrier layer ESL1a disposed between the first interconnection line CL1a and the first via V1a. In an example, the first interconnection line CL1a, the first via V1a, and the first barrier layer ESL1a of the first conductor structure CS1 may have the first side surfaces S1 which may be aligned. The first side surfaces S1 of the first barrier layer ESL1a and the first via V1a may extend linearly from the first side surface S1 of the first interconnection line CL1a.

The second conductor structure CS2 may include a second interconnection line CL1b, a second via V1b, and a second barrier layer ESL1b disposed between the second interconnection line CL1b and the second via V1b. In an example, the second interconnection line CL1b, the second via V1b, and the second barrier layer ESL1b of the second conductor structure CS2 may have second side surfaces S2 which may be aligned. The second side surfaces S2 of the second barrier layer ESL1b and the second via V1b may extend linearly from the second side surface S2 of the second interconnection line CL1b.

The first interconnection line CL1a and the second interconnection line CL1b may extend in the second direction (Y-direction). In an example, the first interconnection line CL1a may include a first conductive barrier layer IL1a and a first conductive layer ML1a on the first conductive barrier layer IL1a. The second interconnection line CL1b may include a second conductive barrier layer IL1b and a second conductive layer ML1b on the second conductive barrier layer IL1b.

The first interconnection line CL1a and the second interconnection line CL1b may have an inclined first side surface S1 of which a width in the first direction (X-direction) may decrease upwardly in the vertical direction (Z-direction).

The first and second interconnection lines CL1a and CL1b may include portions disposed at the same level. In an example, the upper surface of the first interconnection line CL1a may be disposed at a level different from a level of the upper surface of the second interconnection line CL1b. The lower surface of the first interconnection line CL1b may be disposed at a level different from a level of the lower surface of the second interconnection line CL1b. For example, the upper surface of the first interconnection line CL1a may be disposed at a level higher than a level of the upper surface of the second interconnection line CL1b. The lower surface of the first interconnection line CL1a may be disposed at a level higher than a level of the lower surface of the second interconnection line CL1b.

In an example embodiment, the first conductive barrier layer IL1a may not be in contact with the side surface of the first conductive layer ML1a, and the second conductive barrier layer IL1b may not be in contact with the side surface of the second conductive layer ML1b. In an example, widths in the first direction (X-direction) of the upper surfaces of the first and second conductive barrier layers IL1a, IL1b may be smaller than widths in the first direction (X-direction) of lower surfaces of the first and second conductive barrier layers IL1a and IL1b. In an example, the lower surface of the first conductive barrier layer IL1a may be disposed at a level different from a level of the lower surface of the second conductive barrier layer IL1b.

The first and second conductive barrier layers IL1a and IL1b may include a conductive material. For example, the first and second conductive barrier layers IL1a and IL1b may include titanium nitride (TiN).

In an example embodiment, the first conductive layer ML1a may be disposed on the first conductive barrier layer IL1a, and the second conductive layer ML1b may be disposed on the second conductive barrier layer IL1b. In an example, the width in the first direction (X-direction) in the upper region may be smaller than the width in the first direction (X-direction) in the lower region of the first conductive layer ML1a the and the second conductive layer ML1b.

The first and second conductive layers ML1a and ML1b may include a conductive material different from a material of the first and second contact plugs V0a and V0b. In an example, the first and second conductive layers ML1a and ML1b may include ruthenium (Ru).

The first via V1a may be disposed on the first interconnection line CL1a, and the second via V1b may be disposed on the second interconnection line CL1b.

The first interconnection line CL1a may include a first overlapping portion overlapping the first via V1a in the third direction (Z-direction) and a first non-overlapping portion not overlapping the first via V1a in the third direction (Z-direction). In an example, the second interconnection line CL1b may include a second overlapping portion overlapping the second via V1b in the third direction (Z-direction) and a second non-overlapping portion not overlapping the second via V1b in the third direction (Z-direction).

The first thickness h2 in the vertical direction (Z-direction) of the first interconnection line CL1a may be the same or substantially the same as the second thickness h2 in the vertical direction (Z-direction) of the second interconnection line CL1b. For example, a distance from the lower surface of the first interconnection line CL1a to the upper surface of the first interconnection line CL1a may be the same or substantially the same as the distance from the lower surface of the second interconnection line CL1b to the upper surface of the second interconnection line CL1b. In an example embodiment, the area of the first overlapping portion of the first interconnection line CL1a overlapping the first via V1a may be substantially the same as the area of the second overlapping portion of the second interconnection line CL1b overlapping the second via V1b. However, an example embodiment thereof is not limited thereto, and the area of the first overlapping portion of the first interconnection line CL1a overlapping the first via V1a may be greater than the area of the second overlapping portion overlapping of the second interconnection line CL1b the second via V1b.

The first barrier layer ESL1a may be disposed between the first conductive layer ML1a and the first via V1a, and the second barrier layer ESL1b may be disposed between the second conductive layer ML1b and the second via V1b. The first barrier layer ESL1a may be disposed on the lower surface of first via V1a, and may not be disposed on the side surface of first via V1a. The second barrier layer ESL1b may be disposed on the lower surface of the second via V1b and may not be disposed on the side surface of the second via V1b.

Widths in the first direction (X-direction) of the lower regions of the first and second barrier layers ESL1a and ESL1b, in contact with the upper surface of the first and second conductive layers ML1a and ML1b may be greater than widths in the first direction (X-direction) of upper regions in contact with the lower surface of the first and second vias V1a, V1b.

When the first barrier layer ESL1a is disposed at a level higher than a level of the second barrier layer ESL1b, the first thickness t1 of the first barrier layer ESL1a may be smaller than the second thickness t2 of the second barrier layer ESL1b. However, an example embodiment thereof is not limited thereto, and the thickness of the first barrier layer ESL1a′ of the semiconductor device 100′, described later with reference to FIG. 1C, may be the same as the thickness of the second barrier layer ESL1b.

The first barrier layer ESL1a may be disposed between the first overlapping portion of the upper surface of the first interconnection line CL1a overlapping the first via V1a and the lower surface of the first via V1a. The first barrier layer ESL1a may not be disposed on the upper surface of the first non-overlapping portion of the first interconnection line CL1a not overlapping the first via V1a.

The second barrier layer ESL1b may be disposed between the second overlapping portion of the upper surface of the second interconnection line CL1b overlapping the second via V1b and the lower surface of the second via V1b. The second barrier layer ESL1b may not be disposed on the second non-overlapping portion of the upper surface of the second interconnection line CL1b not overlapping the second via V1b.

The first and second barrier layers ESL1a and ESL1b may include ruthenium nitride (RuN).

The first via V1a may be in contact with the upper surface of the first barrier layer ESL1a. The second via V1b may be in contact with the upper surface of the second barrier layer ESL1b.

The first and second vias V1a and V1b may have an inclined first side surface S1 of which a width in the first direction (X-direction) may decrease upwardly in the vertical direction (Z-direction).

The upper surface of first via V1a may be disposed at the same level as the upper surface of second via V1b. That is, the upper surface of the first and second vias V1a and V1b may be disposed at the same level as the upper surface of the interlayer insulating layer 192.

The height of the first via V1a in the vertical direction (Z-direction) may be different from the height of the second via V1b in the vertical direction (Z-direction). In an example, the third height h3 (or thickness) in the vertical direction (Z-direction) of the first via V1a may be smaller than the fourth height h4 (or thickness) in the vertical direction (Z-direction) of the second via V1b. In an example, the third height h3 in the vertical direction (Z-direction) of the first via V1a may be greater than the first thickness h2 in the vertical direction (Z-direction) of the first interconnection line CL1a. However, an example embodiment thereof is not limited thereto, and the fifth height h5 in the vertical direction (Z-direction) of the first via V1a of the semiconductor device 100″ in FIG. 1D may be smaller than the first thickness h2 in the vertical direction (Z-direction) of the first interconnection line CL1a.

The first via V1a and the second via V1b may include the same conductive material as the material of the first and second conductive layers ML1a and ML1b of the first and second interconnection lines CL1a and CL1b. In an example, the first and second vias V1a and V1b may include ruthenium (Ru).

The interlayer insulating layer 192 may be in contact with the first side surface S1 and the second side surface S2 of the first and second conductive structures CS1 and CS2. The interlayer insulating layer 192 may cover the upper surface of the first and second interconnection lines CL1a and CL1b. In an example, the interlayer insulating layer 192 may be in contact with the first and second non-overlapping portions of the upper surfaces of the first and second interconnection lines CL1a and CL1b that do not overlap the first and second vias V1a and V1b.

The semiconductor device according to example embodiments may include first and second contact plugs V0a and V0b, the first conductor structure CS1 on the first contact plug V0a, and the second conductor structure CS2 on the second contact plug V0b having upper surfaces disposed at different levels as on another and the upper surface of the first via V1a of the first conductor structure CS1 and the upper surface of the second via V1b of the second conductor structure CS2 may be disposed at the same level as one another. Accordingly, the degradation of electrical reliability due to a step difference of the upper surfaces of first and second contact plugs V0a and V0b resulting from the upper surfaces of first and second contact plugs V0a and V0b being disposed at different levels may be addressed.

FIGS. 1C and 1D are enlarged diagrams illustrating region A of the semiconductor device illustrated in FIG. 1A.

Referring to FIG. 1C, in a semiconductor device 100′, the components other than the first barrier layer ESL1a′ may be the same as or may correspond to the components illustrated in FIG. 1B. Among the components other than the first and second barrier layers ESL1a′ and ESL1b, redundant descriptions of the same or corresponding components illustrated in FIG. 1B may not be provided.

The semiconductor device 100′ may include first and second barrier layers ESL1a′ and ESL1b having the same thickness. For example, the first and second barrier layers ESL1a′ and ESL1b may have a second thickness t2 in the vertical direction.

Referring to FIG. 1D, the components of the semiconductor device 100″ other than the first barrier layer ESL1a′, the first and second vias V1a″ and V1b″ may be the same as or correspond to the components illustrated in FIG. 1B. Among the components other than the first and second barrier layer ESL1a′ and ESL1b and the first and second vias V1a″, V1b″, redundant descriptions of the same or corresponding components illustrated in FIG. 1B may not be provided.

The semiconductor device 100″ may include a first conductor structure CS1″ and a second conductor structure CS2. The first conductor structure CS1″ may include a first interconnection line CL1a, a first barrier layer ESL1a′ and a first via V1a″. The second conductor structure CS2 may include a second interconnection line CL1b, a second barrier layer ESL1b, and a second via V1b″.

The first and second barrier layers ESL1a′ and ESL1b may have the same thickness in the vertical direction. The fifth height h5 in the vertical direction (Z-direction) of the first via V1a″ may be smaller than the sixth height H6 in the vertical direction (Z-direction) of the second via V1b″. The fifth height h5 in the vertical direction (Z-direction) of the first via V1a″ may be smaller than the first thickness h2 in the vertical direction (Z-direction) of the first interconnection line CL1a.

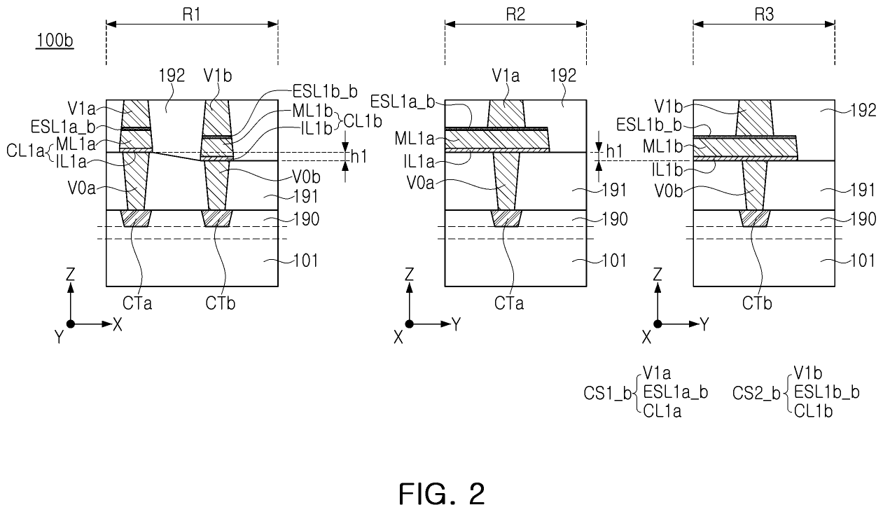

FIGS. 2 to 10 are cross-sectional diagrams illustrating a portion of a semiconductor device according to other example embodiments.

Referring to FIG. 2, the components other than the first barrier layer ESL1a_b of the first conductor structure CS1_b and the second barrier layer ESL1b_b of the second conductor structure CS2_b in the semiconductor device 100b may be the same as or correspond to the components illustrated in FIG. 1A. Among the components other than the first and second barrier layers ESL1a_b and ESL1b_b, redundant descriptions of the same or corresponding components illustrated in FIG. 1A may not be provided.

The semiconductor device 100b may include a first conductor structure CS1_b and a second conductor structure CS2_b. The first conductor structure CS1_b may include a first interconnection line CL1a, a first via V1a, and a first barrier layer ESL1a_b. The second conductor structure CS2_b may include a second interconnection line CL1b, a second via V1b, and a second barrier layer ESL1b_b.

The first barrier layer ESL1a_b and the second barrier layer ESL1b_b of the semiconductor device 100b may cover an upper surface of the first interconnection line CL1a and an upper surface of the second interconnection line CL1b. In an example, the first barrier layer ESL1a_b may be disposed between the first overlapping portion of the upper surface of the first interconnection line CL1a and the lower surface of the first via V1a and on the first non-overlapping portion of the upper surface of the first interconnection line CL1a not overlapping the first via V1a. The second barrier layer ESL1b_b may be disposed between the second overlapping portion of the upper surface of second interconnection line CL1b and the lower surface of the second via V1b and on the second non-overlapping portion of the upper surface of second interconnection line CL1b not overlapping the second via V1b. In an example embodiment, the interlayer insulating layer 192 of the semiconductor device 100b may cover the first barrier layer ESL1a_b disposed on the first non-overlapping portion of first interconnection line CL1a and the second barrier layer ESL1b_b disposed on the second non-overlapping portion of the second interconnection line CL1b. The interlayer insulating layer 192 of the semiconductor device 100b may be in contact with the first barrier layer ESL1a_b disposed on the first non-overlapping portion of the first interconnection line CL1a and the second barrier layer ESL1b_b disposed on the second non-overlapping portion of the second interconnection line CL1b.

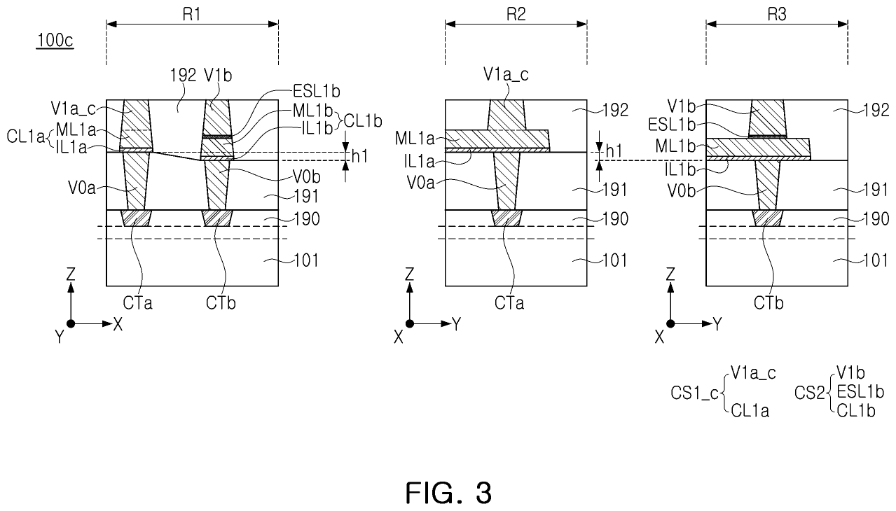

Referring to FIG. 3, the components other than the first conductor structure CS1_c in the semiconductor device 100c may be the same as or correspond to the components illustrated in FIG. 1A. Among the components other than the first conductor structure CS1_c, redundant descriptions of the same or corresponding components illustrated in FIG. 1A may not be provided.

The semiconductor device 100c may include a first conductor structure CS1_c and a second conductor structure CS2. The first conductor structure CS1_c may include a first interconnection line CL1a and a first via V1a_c in contact with the upper surface of the first interconnection line CL1a. The first via V1a_c may be disposed directly on the upper surface of the first interconnection line CL1a. That is, the first via V1a_c may be in contact with the upper surface of the first interconnection line CL1a.

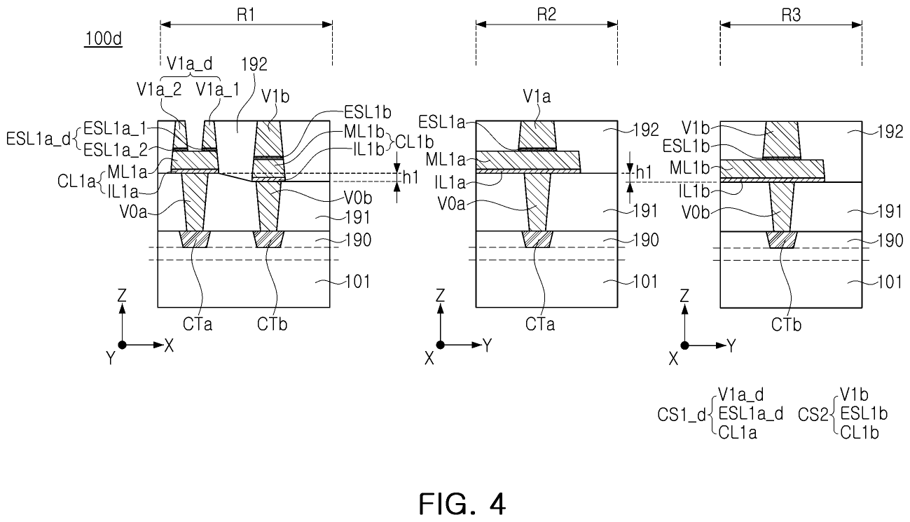

Referring to FIG. 4, the components other than the first conductor structure CS1_d in the semiconductor device 100d may be the same as or correspond to the components illustrated in FIG. 1A. Among the components other than the first conductor structure CS1_d, redundant descriptions of the same or corresponding components illustrated in FIG. 1A may not be provided.

The semiconductor device 100d may include a first conductor structure CS1_d and a second conductor structure CS2. The first conductor structure CS1_d may include a first interconnection line CL1a, a first barrier layer ESL1a_d, and a first via V1a_d. The first via V1a_d may be disposed on the first interconnection line CL1a. The first via V1a_d may include a 1-1 via V1a_1 and a 1-2 via V1a_2 spaced apart from each other on the first interconnection line CL1a.

The upper surface of the first interconnection line CL1a may include a first overlapping portion overlapping a 1-1 via V1a_1 and a 1-2 via V1a_2 and a first non-overlapping portion not overlapping a 1-1 via V1a_1 and a 1-2 via V1a_2.

The first barrier layer ESL1a_d may include a 1-1 barrier layer ESL1a_1 disposed on the first overlapping portion of the first interconnection line CL1a and the lower surface of the 1-1 via V1a_1 and a 1-2 barrier layer ESL1a_2 disposed on the first overlapping portion of the first interconnection line CL1a and the lower surface of the 1-2 via V1a_2. In an example, the first barrier layer ESL1a_d may not be disposed on the first non-overlapping portion of the first interconnection line CL1a. A portion of the upper surface of the first interconnection line CL1a may be exposed through a space between the 1-1 via V1a_1 and the 1-2 via V1a_2.

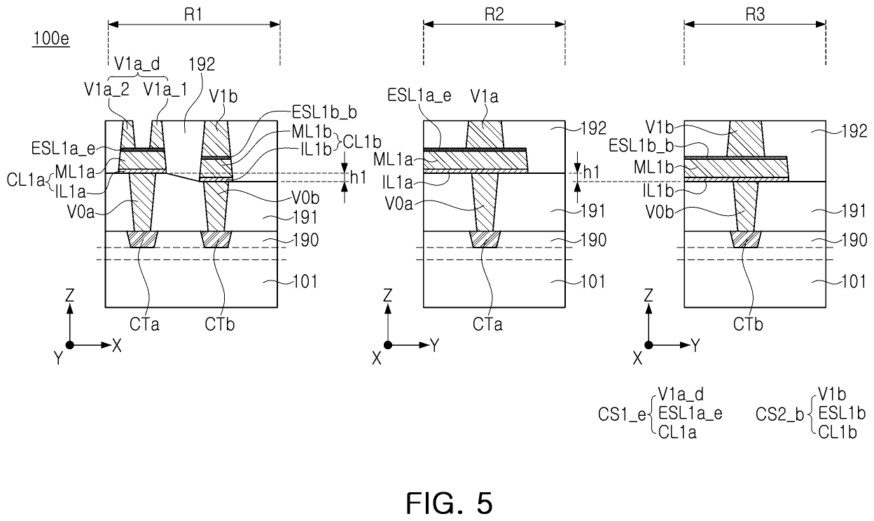

Referring to FIG. 5, the components other than the first conductor structure CS1_e in the semiconductor device 100e may be the same as or correspond to the components illustrated in FIG. 1A. Among the components other than the first conductor structure CS1_e, redundant descriptions of the same or corresponding components illustrated in FIG. 1A may not be provided.

The semiconductor device 100e may include a first conductor structure CS1_e and a second conductor structure CS2. The first conductor structure CS1_e may include a first interconnection line CL1a, a first barrier layer ESL1a_e, and a first via V1a_d. The first via V1a_d may be disposed on the first interconnection line CL1a. The first via V1a_d may include a 1-1 via V1a_1 and a 1-2 via V1a_2 spaced apart from each other on the first interconnection line CL1a.

The upper surface of the first interconnection line CL1a may include the first overlapping portion overlapping the 1-1 via V1a_1 and the 1-2 via V1a_2 and the first non-overlapping portion overlapping the 1-1 via V1a_1 and the 1-2 via V1a_2.

The first barrier layer ESL1a_e may cover the upper surface of the first interconnection line CL1a. In an example, the first barrier layer ESL1a_e may be disposed on the first overlapping portion and the first non-overlapping portion of the first interconnection line CL1a. The second barrier layer ESL1b_b may be disposed on the second overlapping portion and the second non-overlapping portion of the upper surface of the second interconnection line CL1b.

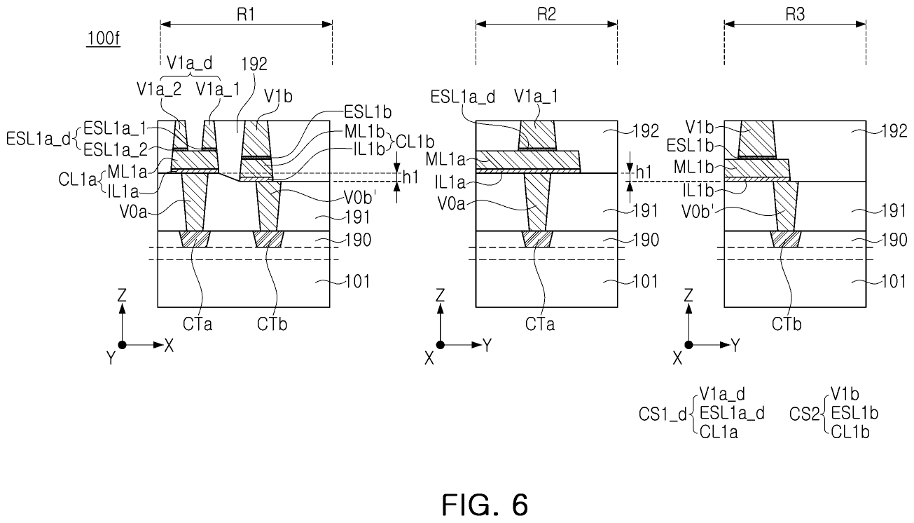

Referring to FIG. 6, the components other than the second contact plug V0b′ in the semiconductor device 100f may be the same as or correspond to the components illustrated in FIG. 1A. The first and second conductor structures CS1_d and CS2 of the semiconductor device 100f may correspond to the first and second conductor structures CS1_d and CS2 of the semiconductor device 100d in FIG. 4. Among the components other than second contact plug V0b′, redundant descriptions of the same or corresponding components illustrated in FIGS. 1A and 4 may not be provided.

A portion of the upper surface of the second contact plug V0b′ may be exposed. In an example, a portion of the upper surface of the second contact plug V0b′ may be covered by the second conductor structure CS2, and the other portion of the upper surface of the second contact plug V0b′ may be covered by the interlayer insulating layer 192.

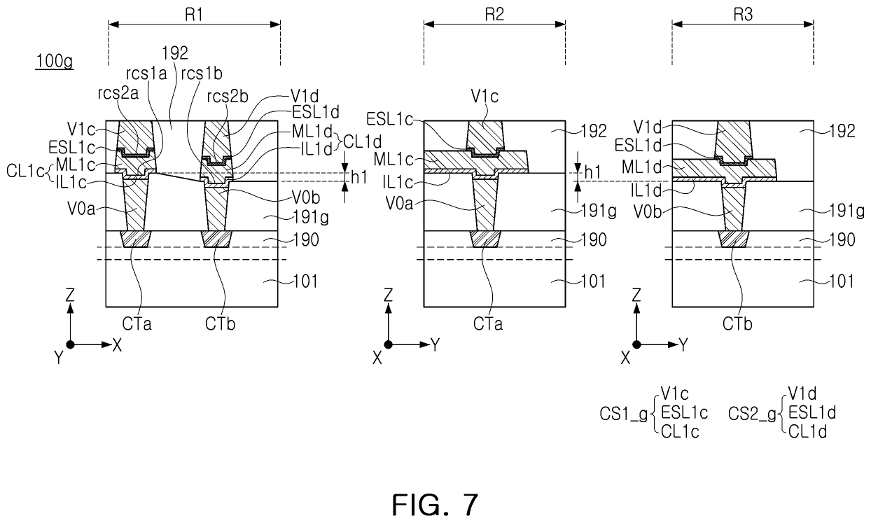

Referring to FIG. 7, in a semiconductor device 100g, the components other than the first conductor structure CS1_g and the second conductor structure CS2_g may be the same as or correspond to the components illustrated in FIG. 1A. Among the components other than the first conductor structure CS1_g and the second conductor structure CS2_g, redundant descriptions of the same or corresponding components illustrated in FIG. 1A may not be provided.

The semiconductor device 100g may include a first conductor structure CS1_g and a second conductor structure CS2_g. The first conductor structure CS1_g may include a first interconnection line CL1c, a first via V1c and a first barrier layer ESL1c disposed between the first interconnection line CL1c and the first via V1c. In an example, the second conductor structure CS2_g may include a second interconnection line CL1d, a first via V1d, and a second barrier layer ESL1d disposed between the second interconnection line CL1d and the second via V1d. In an example, the first interconnection line CL1c may include the first conductive barrier layer IL1c and the first conductive layer MLIc on the first conductive barrier layer IL1c. The second interconnection line CL1d may include a second conductive barrier layer IL1d and a second conductive layer ML1d on the second conductive barrier layer IL1d.

The upper surface of the second lower insulating structure 191g may include second portions disposed at a level lower than a level of the first portions and in contact with the upper surfaces of the first and second contact plugs V0a and V0b. A lowermost surface of the second interconnection line CL1d may be disposed at a level lower than a level of a level of a lowermost surface of the first interconnection line CL1c.

The lower surface of the first interconnection line CL1c may be disposed at a level lower than a level of a level of the first portion of the second lower insulating structure 191g, and may be in contact with the second portion exposing the upper surface of the first contact plug V0a. The lower surface of the second interconnection line CL1d may be disposed at a level lower than a level of a level of the first portion of the second lower insulating structure 191g and may be in contact with the second portion exposing the upper surface of the second contact plug V0b.

The lower surface of the first interconnection line CL1c may include a first protruding surface rcs1a protruding toward the upper surface of the first contact plug VOa. The lower surface and the upper surface of the first interconnection line CL1c may correspond to the surface profile of the upper surface of the second lower insulating structure 191g.

The lower surface of the second interconnection line CL1d may include a second protruding surface rcs1b protruding toward the upper surface of the first contact plug VOb. The lower surface of the second interconnection line CL1d may be disposed at a level lower than a level of a level of the lower surface of the first interconnection line CL1c, and may correspond to a surface profile of the upper surface of the second lower insulating structure 191g. The upper surface of the second interconnection line CL1d may have a surface profile corresponding to the lower surface of the second interconnection line CL1d.

The first barrier layer ESL1c may be disposed between the first interconnection line CL1c and the first via V1c. Each of the first barrier layer ESL1c and the second barrier layer ESL1d may include a central portion and an edge portion extending from the central portion and disposed at a level higher than a level of the central portion. The central portion of the first barrier layer ESL1c may correspond to the first recess surface rcs1a of the first interconnection line CL1c. The central portion of the second barrier layer ESL1d may correspond to the second protruding surface rcs1b of the second interconnection line CL1d.

The lower surface of the first via V1c may include a third protruding surface rcs2a protruding toward the central portion of the first barrier layer ESL1c. In an example, the lower surface of the second via V1d may include a fourth protruding surface rcs2b protruding toward the central portion of the second barrier layer ESL1d.

The upper surface of first via V1c and the upper surface of second via V1d may have a flat surface profile. In an example, the upper surface of the first via V1c may be disposed at the same level as the upper surface of the second via V1d and the upper surface of the interlayer insulating layer 192.

The first barrier layer ESL1c may be disposed between the first overlapping portion of the first interconnection line CL1c and the lower surface of the first via V1c. The first barrier layer ESL1c may not be disposed on the first non-overlapping portion of the first interconnection line CL1c. However, an example embodiment thereof is not limited thereto, and the first barrier layer ESL1c may cover the upper surface of the first interconnection line CL1c, such that the first barrier layer ESL1c may extend from the first overlapping portion of the first interconnection line CL1c and the lower surface of the first via V1c to the first non-overlapping portion of the first interconnection line CL1c.

The second barrier layer ESL1d may be disposed between the second overlapping portion of the second interconnection line CL1d and the lower surface of the second via V1d. The second barrier layer ESL1d may not be disposed on the second non-overlapping portion of the second interconnection line CL1d. However, an example embodiment thereof is not limited thereto, and the second barrier layer ESL1d may cover the upper surface of the second interconnection line CL1d, such that the second barrier layer ESL1d may extend from the second overlapping portion of the second interconnection line CL1d and the lower surface of the second via V1d to the second non-overlapping portion of the second interconnection line CL1d.

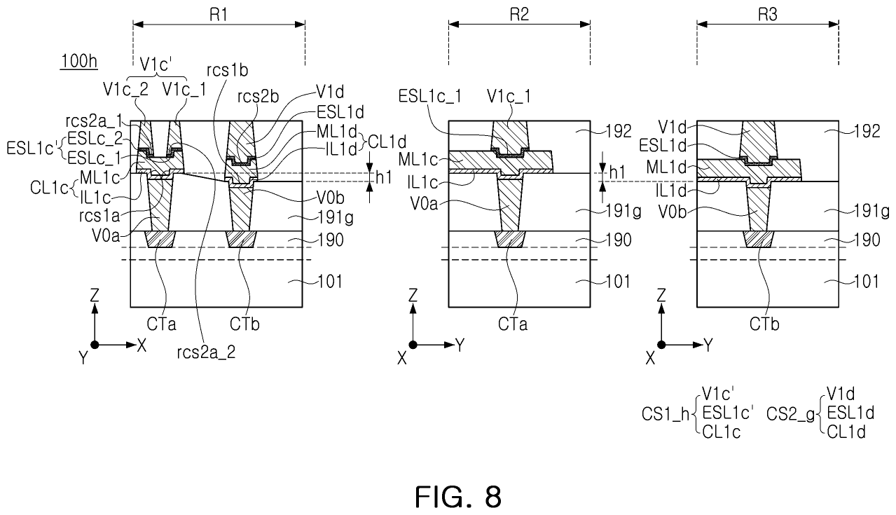

Referring to FIG. 8, in a semiconductor device 100h, the components other than the first conductor structure CS1_h and the second conductor structure CS2_g may be the same as or correspond to the components illustrated in FIG. 1A. Among the components other than first conductor structure CS1_h and the second conductor structure CS2_g, redundant descriptions of the same or corresponding components illustrated in FIG. 1A may not be provided.

The semiconductor device 100h may include a first conductor structure CS1_h disposed on the first contact plug V0a and a second conductor structure CS2_g disposed on the second contact plug V0b. The second conductor structure CS2_g of the semiconductor device 100h may correspond to the second conductor structure CS2_g of the semiconductor device 100g in FIG. 7. The second conductor structure CS2_g of the semiconductor device 100h may correspond to the second conductor structure CS2g of the semiconductor device 100g in FIG. 7.

The first conductor structure CS1_h may include a first interconnection line CL1c, a first barrier layer ESL1c′, and a first via V1c′.

The first interconnection line CL1c of the first conductor structure CS1_h may correspond to the first interconnection line CL1c of the first conductor structure CS1_g in FIG. 7. The lower surface of the first interconnection line CL1c may include the first protruding surface rcs1a protruding toward the upper surface of the first contact plug V0a.

The first via V1c′ may include a 1-1 via V1c_1 and a 1-2 via V1c_2 spaced apart from each other on the first interconnection line CL1c. In an example, the first barrier layer ESL1c′ may include a 1-1 barrier layer ESL1c_1 disposed between the first overlapping portion of first interconnection line CL1c and the lower surface of the 1-1 via V1c_1 and a 1-2 barrier layer ESL1c_2 disposed on the first overlapping portion of the first interconnection line CL1c and the lower surface of the 1-2 via V1c_2.

Each of the 1-1 barrier layer ESL1c_1 and the 1-2 barrier layer ESL1c_2 may have a step difference surface according to the surface profile of the upper surface of the first interconnection line CL1c. In an example, the 1-1 barrier layer ESL1c_1 and the 1-2 barrier layer ESL1c_2 may include a first portion protruding toward the central portions of the first and second protruding surfaces rcs1a and res1b and a second portion adjacent to side surfaces of the first and second interconnection lines CL1c, CL1d and disposed at a level higher than a level of the first portion.

The lower surface of the 1-1 via V1c_1 may include a 3-2 protruding surface rcs2a_2 protruding toward the first protruding surface rcs1a of the first interconnection line CL1c, and the lower surface of the 1-2 via V1c_2 may include a 3-1 protruding surface rcs2a_1 protruding toward the first protruding surface rcs1a of the first interconnection line CL1c.

The upper surface of the first via V1c′ and the upper surface of the second via V1d may have a flat surface profile. In an example, the upper surface of the first via V1c′ may be disposed at the same level as the upper surface of the second via V1d and the upper surface of the interlayer insulating layer 192.

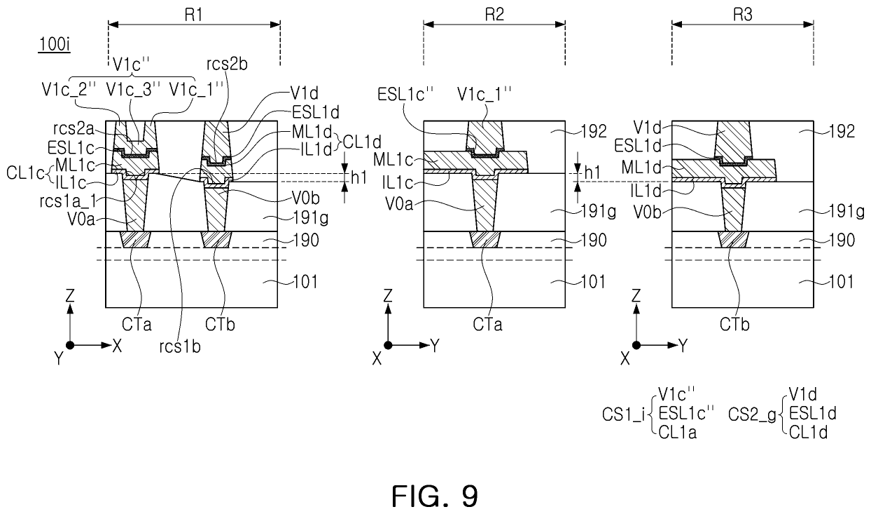

Referring to FIG. 9, in a semiconductor device 100i, the components other than the first conductor structure CS1_i and the second conductor structure CS2_g may be the same as or correspond to the components illustrated in FIG. 1A. Among the components other than the first conductor structure CS1_i and the second conductor structure CS2_g, redundant descriptions of the same or corresponding components illustrated in FIG. 1A may not be provided.

The semiconductor device 100i may include a first conductor structure CS1_i disposed on the first contact plug V0a and a second conductor structure CS2_g disposed on the second contact plug V0b. The second conductor structure CS2_g of the semiconductor device 100i may correspond to the second conductor structure CS2_g of the semiconductor device 100g in FIG. 7.

The first conductor structure CS1_i may include a first interconnection line CL1c, a first barrier layer ESL1c, and a first via V1c″. In an example, the first interconnection line CL1c of the first conductor structure CS1_i may correspond to the first interconnection line CL1c in FIG. 7 and/or FIG. 8. The first barrier layer ESL1c of the first conductor structure CS1_i may correspond to the first barrier layer ESL1c in FIG. 7.

The first barrier layer ESL1c of the first conductor structure CS1_i may be disposed between the first interconnection line CL1c and the lower surface of the first via V1c″. The first via V1c″ may include a first branch via portion V1c_1″ and a second branch via portion V1c_2″ extending from the body portion V1c_3″ and the body portion V1c_3″ and spaced apart from the body portion V1c_3″.

The lower surface of the first via V1c″ may include a third protruding surface rcs2a protruding toward the central portion of the first barrier layer ESL1c. In an example, the lower surface of the body portion V1c_3″ may be a lower surface of the first via V1c″, and may include a third protruding surface rcs2a in contact with the upper surface of the first barrier layer ESL1c and protruding toward the central portion of the first barrier layer ESL1c. The first branch via portion V1c_1″ and the second branch via portion V1c_2″ may extend from the upper surface of the body portion V1c_3″. The first branch via portion V1c_1″ and the second branch via portion V1c_2″ may be spaced apart from each other in the horizontal direction.

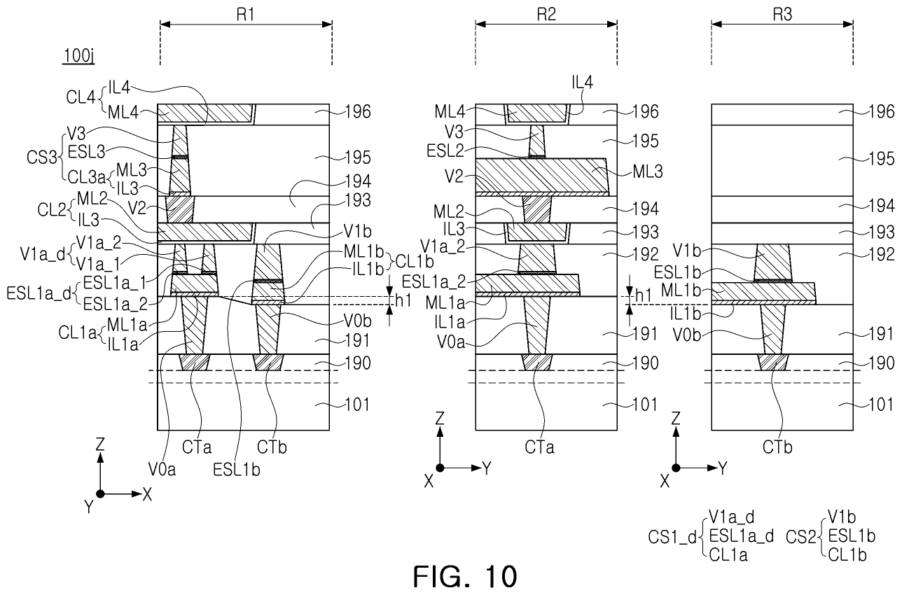

Referring to FIG. 10, a semiconductor device 100j may include a first conductor structure CS1d on the first contact plug V0a, a second conductor structure CS2 on the second contact plug V0b, a first upper conductive pattern CL2 on the first conductor structure CS1d, a third contact plug V2 on the first upper conductive pattern CL2, a third conductor structure CS3 on the third contact plug V2, and a third conductor structure CS3 the second upper conductive pattern CL4.

The first conductor structure CS1d and the second conductor structure CS2 of the semiconductor device 100j may correspond to the first conductor structure CS1_d and the second conductor structure CS2 of the semiconductor device 100d in FIG. 4.

The semiconductor device 100j may further include a second interlayer insulating layer 193 disposed on the first and second conductor structure CS1_d and CS2 and surrounding a side surface of the first upper conductive pattern CL2, a third interlayer insulating layer 194 disposed on the second interlayer insulating layer 193 and surrounding a side surface of the third contact plug V2, a fourth interlayer insulating layer 195 disposed on the third interlayer insulating layer 194 and in contact with a side surface of the third conductor structure CS3, and a fifth interlayer insulating layer 196 disposed on the fourth interlayer insulating layer 195, surrounding the side surface of the second upper conductive pattern CLA, and exposing an upper surface of the fourth upper conductive pattern CL4. Each of the second to fifth interlayer insulating layers 192-196 may include at least one of silicon oxide or silicon nitride.

The first upper conductive pattern CL2 may have a width increasing upwardly in the vertical direction (Z-direction). The first upper conductive pattern CL2 may include a first upper conductive barrier layer IL3 and a first upper conductive layer ML2. The first upper conductive barrier layer IL3 may cover the lower surface of the first upper conductive layer ML2 and the side surface of the first upper conductive layer ML2. The first upper conductive pattern CL2 may be provided and/or formed by a damascene process. The first upper conductive layer ML2 may include copper (Cu). The first upper conductive barrier layer IL3 may include metal nitride, for example, at least one of titanium nitride (TiN), tantalum nitride (TaN), or tungsten nitride (WN).

The third contact plug V2 may be disposed on the upper surface of the first upper conductive pattern CL2. The third contact plug V2 may be disposed between the first upper conductive pattern CL2 and the third conductor structure CS3, and may electrically connect the first upper conductive pattern CL2 to the third conductor structure CS3.

The third conductor structure CS3 may be disposed on the third contact plug V2. The third conductor structure CS3 may correspond to the first conductor structure CS1 illustrated in FIG. 1A. The third conductor structure CS3 may include a third interconnection line CL3a, a third via V3, and a third barrier layer ESL3 disposed between the third interconnection line CL3a and the lower surface of the third via V3.

The second upper conductive pattern CLA may be disposed on the third via V3 of the third conductor structure CS3. The second upper conductive pattern CL4 may have a width increasing upwardly in the vertical direction (Z-direction). The second upper conductive pattern CL4 may include a second upper conductive barrier layer IL4 and a second upper conductive layer ML4. The second upper conductive barrier layer IL4 may cover the lower surface of the second upper conductive layer MLA and the side surface of the second upper conductive layer ML4. The second upper conductive pattern CL4 may be provided and/or formed by a damascene process. The second upper conductive layer ML4 may include copper (Cu). The second upper conductive barrier layer IL4 may include metal nitride, for example, at least one of titanium nitride (TiN), tantalum nitride (TaN), or tungsten nitride (WN).

FIG. 11A is a plan diagram illustrating a portion of a semiconductor device according to an example embodiment. FIG. 11B is a cross-sectional diagram illustrating a portion of the semiconductor device in FIG. 11A, taken along lines I-I′ and II-II′. For ease of description, only a portion of the components of the semiconductor device are illustrated in FIG. 11A.

Referring to FIGS. 11A and 11B, the semiconductor device 100 may include a substrate 101 including an active region 105, channel structures 140 including first to fourth channel layers 141, 142, 143, and 144 vertically spaced apart from each other on the active region 105, a gate structure 160 extending across the active region 105 and each including a gate electrode 165, source/drain regions 130 in contact with the channel structure 140, internal spacers 150 disposed between the gate structure 160 and the source/drain region 130 below each of the channel layers 141, 142, 143, and 144, a first contact structure CT_1 connected to the gate electrode 165, and a second contact structure CT_2 connected to the source/drain regions 130. The semiconductor device 100 may further include a device isolation layer 110 and an interlayer insulating layer 170.

In the semiconductor device 100, the active region 105 may have a fin structure, and the gate electrode 165 may be disposed between the active region 105 and the channel structure 140, between the first to fourth channel layers 141, 142, 143, and 144 of the channel structure 140, and on channel structure 140. Accordingly, the semiconductor device 100 may include transistors of multi-bridge channel FET (MBCFET™) structure, which is a gate-all-around (GAA) field effect transistor.

The substrate 101 may have an upper surface extending in the first direction (X-direction) and the second direction (Y-direction). The substrate 101 may include a semiconductor material, such as a group IV semiconductor, a group III-V compound semiconductor, or a group II-IV compound semiconductor. For example, a group IV semiconductor may include silicon, germanium, or silicon-germanium. The substrate 101 may be provided as a bulk aper, epitaxial layer, silicon on insulator (SOI), or semiconductor on insulator (SeOI) layer.

The substrate 101 may include the active region 105 disposed in an upper portion. The active region 105 may be defined by the device isolation layer 110 in the substrate 101 and may extend in the first direction (X-direction). However, depending on the descriptions, the active region 105 may be described as a component separate from the substrate 101. The active region 105 may partially protrude from the device isolation layer 110, such that the upper surface of the active region 105 may be disposed at a level higher than a level of the upper surface of the device isolation layer 110. The active region 105 may include a portion of the substrate 101 and may include an epitaxial layer grown from the substrate 101. However, the active region 105 may be partially recessed on both sides of the gate structure 160 such that recess regions may be formed, and the source/drain regions 130 may be disposed in the recess regions.

In example embodiments, the active region 105 may or may not include a well region including impurities. For example, for a P-type transistor pFET, the well region may include N-type impurities such as phosphorus (P), arsenic (As), or antimony (Sb), and for an N-type transistor nFET, the well region may include P-type impurities such as boron (B), gallium (Ga), or indium (In). The well region may be disposed at a predetermined depth from the upper surface of the active region 105, for example.

The device isolation layer 110 may define the active region 105 in the substrate 101. The device isolation layer 110 may be formed, for example, by a shallow trench isolation (STI) process. The device isolation layer 110 may expose the upper surface of the active region 105 and may partially expose the upper portion. In some example embodiments, the device isolation layer 110 may have a curved upper surface having an increasing level toward the active region 105. The device isolation layer 110 may be formed of an insulating material. The device isolation layer 110 may be, for example, oxide, nitride, or a combination thereof.

The gate structures 160 may extend in the second direction (Y-direction) on the active region 105 and the channel structures 140. Functional channel regions of transistors may be formed in the active region 105 and/or the channel structures 140. Each of the gate structures 160 may include a gate electrode 165, gate dielectric layers 162 between the gate electrode 165 and the first to fourth channel layers 141, 142, 143, and 144, and gate spacer layers 164 on side surfaces of the gate electrode 165.

The gate dielectric layers 162 may be disposed between the active region 105 and the gate electrode 165 and between the channel structure 140 and the gate electrode 165, and may be disposed to cover at least a portion of the surfaces of the gate electrode 165. For example, the gate dielectric layers 162 may be disposed to surround the entirety of surfaces other than the upper surface of the gate electrode 165. The gate dielectric layers 162 may be in contact with internal spacer layers 164 below the plurality of channel layers 141, 142, 143, and 144, and may be spaced apart from the source/drain regions 130 by the internal spacers 150. The gate dielectric layers 162 may extend between the gate electrode 165 and the gate spacer layers 164, but an example embodiment thereof is not limited thereto. The gate dielectric layers 162 may include oxide, nitride, or a high-K material. The high-K material may indicate a dielectric material having a dielectric constant higher than that of silicon oxide. The high-K material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In example embodiments the gate dielectric layer 162 may be formed as a multilayer film.

The gate electrode 165 may fill a space between the first to fourth channel layers 141, 142, 143, and 144 on the active region 105 and may extend to the channel structure 140. The gate electrode 165 may be spaced apart from the first to fourth channel layers 141, 142, 143, and 144 by the gate dielectric layers 162. The gate electrode 165 may include a conductive material, for example, a metal nitride such as titanium nitride (TiN), tantalum nitride (TaN), or tungsten nitride (WN), and/or aluminum (Al), tungsten (W), or may include a metal material such as molybdenum (Mo) or semiconductor materials such as doped polysilicon. In example embodiments, the gate electrode 165 may include two or more multilayers.

The gate spacer layers 164 may be disposed on both side surfaces of the gate electrode 165 on the channel structure 140. The gate spacer layers 164 may insulate the source/drain regions 130 and the gate electrode 165 from each other. The gate spacer layers 164 may be formed in a multilayer structure in example embodiments. The gate spacer layers 164 may be formed of at least one of oxide, nitride, or oxynitride, and, for example, may be formed as a low dielectric constant film.

The channel structures 140 may be disposed on the active region 105 in regions in which the active region 105 intersects the gate structures 160. Each of the channel structures 140 may include first to fourth channel layers 141, 142, 143, and 144, which are a plurality of channel layers spaced apart from each other in the third direction (Z-direction). The first to fourth channel layers 141, 142, 143, and 144 may be disposed in order downwardly, and the first channel layer 141 may be an uppermost channel layer. The channel structures 140 may be connected to the source/drain regions 130. The channel structures 140 may have a width the same as or similar to a width of the gate structures 160 in the first direction (X-direction), and may have a width the same as or smaller than a width of the active region 105 in the second direction (Y-direction). In the cross-sectional surface in the second direction (Y-direction), the channel layer disposed in a lower portion of the first to fourth channel layers 141, 142, 143, and 144 may have a width the same or greater than the channel layer disposed in an upper portion. The number of channel layers included in the one channel structure 140 and the shape thereof may be varied in example embodiments. For example, the channel structure 140 may include three channel layers, two channel layers, or five or more channel layers.

The channel structures 140 may be formed of a semiconductor material, and may include, for example, at least one of silicon (Si), silicon germanium (SiGe), or germanium (Ge). The channel structures 140 may be formed of the same material as a material of the active region 105, for example. In some example embodiments, the channel structures 140 may include an impurity region disposed in a region adjacent to the source/drain regions 130.

The source/drain regions 130 may be disposed in regions partially recessed into an upper portion of the active region 105 on both sides of the gate structures 160. The recess regions may extend along side surfaces of the channel structures 140 and side surfaces of the gate dielectric layers 162. The source/drain regions 130 may be disposed to cover different side surfaces in the first direction (X-direction) of each of the first to fourth channel layers 141, 142, 143, and 144 of the channel structures 140. The upper surfaces of the source/drain regions 130 may be disposed at the same level or a level higher than a level of the lower surfaces of the gate electrodes 165 on the channel structures 140. The levels may be varied in example embodiments. The side surfaces of the source/drain regions 130 may have curved portions according to the first to fourth channel layers 141, 142, 143, 144 and the internal spacers 150. The side surfaces of the source/drain regions 130 may have a shape protruding into the gate structure 160 between the plurality of channel layers 141, 142, 143, and 144. However, the specific shape of the side surfaces of the source/drain regions 130 may be varied in example embodiments. The source/drain regions 130 may be an epitaxially grown region and may include a plurality of epitaxial layers. The epitaxially grown surface of the source/drain regions 130 may be in contact with the channel structures 140, the internal spacers 150, and the interlayer insulating layer 170.

The source/drain regions 130 may include at least one of semiconductor materials, for example, silicon (Si) or germanium (Ge), and may further include dopants. For example, when the semiconductor device 100 is an N-type transistor, the dopants may be at least one of phosphorus (P), arsenic (As), and antimony (Sb). For example, when the semiconductor device is a P-type transistor, the dopants may be at least one of boron (B), gallium (Ga), and indium (In). In example embodiments, the source/drain regions 130 may include a plurality of epitaxial layers.

The interlayer insulating layer 170 may be disposed on the device isolation layer 110 to cover the upper surface of the device isolation layer 110 and the source/drain region 130. The interlayer insulating layer 170 may include at least one of oxide, nitride, or oxynitride, and may include, for example, a low dielectric constant material. In example embodiments, the interlayer insulating layer 170 may include a plurality of insulating layers.

The internal spacers 150 may be disposed between the gate structure 160 and the source/drain region 130 below each of the plurality of channel layers 141, 142, 143, and 144 on the active region 105. The internal spacers 150 may be disposed parallel to the gate electrode 165 between the first to fourth channel layers 141, 142, 143, and 144 in the third direction (Z-direction). The internal spacers 150 may cover side surfaces in the first direction (X-direction) of the gate structure 160 below the channel structure 140. The gate electrode 165 may be stably spaced apart from the source/drain region 130 by the internal spacers 150 and may be electrically isolated. The internal spacers 150 below the second to fourth channel layers 142, 143, and 144 may be disposed between channel layers adjacent to the first channel layer 141, the internal spacers 150 below the first channel layer 141 may be disposed between adjacent channel layers, and the internal spacer 150 below the first channel layer 141 may be disposed between the first channel layer 141 and the active region 105. An upper end and a lower end of a side surface of the internal spacers 150 opposing the gate electrode 165 may have a shape protruding toward the gate electrode 165. The internal spacers 150 may have side surfaces concave toward the gate electrode 165. That is, the gate electrode 165 may have a shape convex toward the internal spacers 150. As the side surface of the source/drain region 130 has a shape protruding in the direction of the gate electrode 165 between the plurality of channel layers 141, 142, 143, and 144, the side surface in contact with the source/drain region 130 of the internal spacers 150 may have an inwardly curved shape toward the source/drain region 130.

The first contact structure CT_1 may be disposed on the gate electrode 165. The first contact structure CT_1 may be connected to gate electrode 165 and may apply an electrical signal to the gate electrode 165. The first contact structure CT_1 may be in contact with the upper surface of the gate electrode 165. The first contact structure CT_1 may have inclined side surfaces such that a width thereof decreases toward the substrate 101, but an example embodiment thereof is not limited thereto.

The second contact structure CT_2 may be disposed on the source/drain region 130. The second contact structure CT_2 may be connected to the source/drain region 130 and may apply an electrical signal to the source/drain region 130. The second contact structure CT_2 may be recessed into the source/drain regions 130 and may extend into the source/drain region 130. The second contact structure CT_2 may have inclined side surfaces such that a width thereof decreases toward the substrate 101 due to an aspect ratio, but an example embodiment thereof is not limited thereto. As in the example embodiment, the second contact structure CT_2 may extend from a lower portion of the channel structure 140 below the lower surface of the fourth channel layer 144, which is the fourth channel layer, and may extend to a level lower than a level of the lower surface of the second channel layer 142 or the third channel layer 143 in example embodiments. The second contact structure CT_2 may include a metal material such as, for example, tungsten (W), cobalt (Co), molybdenum (Mo), copper (Cu), ruthenium (Ru), or aluminum (Al).

Each of the first and second contact structures CT_1 and CT_2 may correspond to the first contact structure CTa and/or the second contact structure CTb in FIG. 1A.

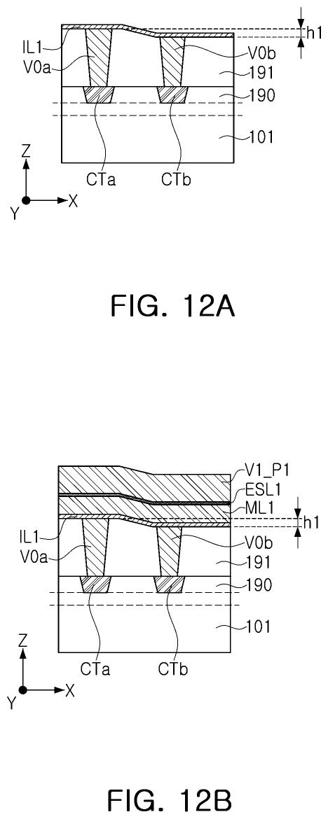

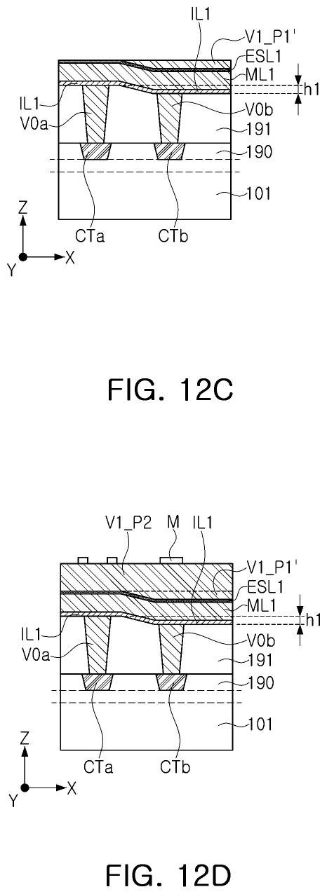

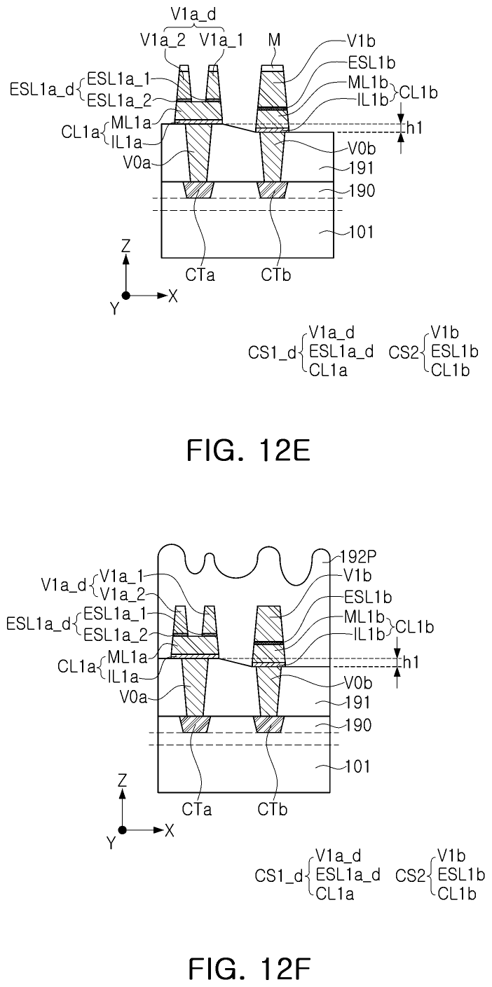

FIGS. 12A to 12F are diagrams illustrating a method of manufacturing the semiconductor device in FIG. 4 according to example embodiments.

Referring to FIG. 12A, a first lower insulating structure 190 may be formed on the substrate 101, first and second contact structures CTa and CTb penetrating through at least a portion of the first lower insulating structure 190 may be formed, a second lower insulating structure 191 may be on the first and second contact structures CTa and CTb and first lower insulating structure 190, first and second contact plugs V0a and V0b penetrating through the second lower insulating structure 191 and connected to the first and second contact structures CTa and CTb may be formed, and a barrier layer IL1 may be formed on the first and second contact plugs V0a and V0b and the second lower insulating structure 191. In an example embodiment, the forming of the first and second contact plugs V0a and V0b may include forming openings penetrating the second lower insulating structure 191 and exposing the first and second contact structures CTa and CTb, forming a conductive material layer filling the openings and covering the upper surface of the second lower insulating structure 191, and performing a chemical-mechanical polishing process to remove a conductive material layer from the upper surface of the second lower insulating structure 191 and remaining (e.g., leaving) the conductive material layer in the openings.

The first and second contact plugs V0a and V0b formed by the chemical mechanical polishing process may have upper surfaces disposed at different levels.

In an example, the upper surface of the first contact plug V0a may be formed at a level higher than a level of the upper surface of the second contact plug V0b. Accordingly, a step difference h1 may be formed depending on a level difference between the upper surface of the first contact plug V0a and the upper surface of the second contact plug V0b.

The second lower insulating structure 191 may be formed to surround side surfaces of the first and second contact plugs V0a and V0b. The upper surface of the second lower insulating structure 191 may include a first portion exposing the upper surface of the first contact plug V0a and a second portion exposing the upper surface of the second contact plug V0b. The first portion of the upper surface of the second lower insulating structure 191 may be at a level higher than a level of the second portion of the upper surface of the second lower insulating structure 191.

The barrier layer IL1 may be formed to cover the second lower insulating structure 191. The barrier layer IL1 may be formed according to the surface profile of the upper surface of the second lower insulating structure 191. That is, the second portion of the barrier layer IL1 covering the upper surface of the second contact plug V0b may be formed at a level lower than a level of a level of the first portion of the barrier layer IL1 covering the upper surface of the first contact plug V0a.

Referring to FIG. 12B, the first conductive pattern ML1, the first conductive liner ESL1, and the second conductive pattern V1_P1 may be formed in order on the barrier layer IL1. In an example, the first conductive pattern ML1 and the second conductive pattern V1_P1 may include ruthenium (Ru), and the first conductive liner ESL1 may include ruthenium nitride (RuN). In an example, a height of the first conductive pattern ML1 in the third direction (Z-direction) may be smaller than a height of the second conductive pattern V1_P1 in the third direction (Z-direction).

Referring to FIG. 12C, a chemical mechanical polishing process (CMP) may be performed on the second conductive pattern V1_P1 throughout the entire region to expose a portion of the first conductive liner ESL1 disposed at the highest level among the first conductive liners ESL1. The first conductive liner ESL1 disposed at the highest level among the first conductive liners ESL1 may work as a planarization stop layer for a chemical mechanical polishing process.

Accordingly, the step difference according to the level difference between the upper surface of the first contact plug V0a and the upper surface of the second contact plug V0b may be removed (or reduced). In an example, a portion of the first conductive liner ESL1 exposed while performing the CMP process for the second conductive pattern V1_P1 may be removed. Accordingly, the thickness of the first conductive liner ESL1 may not be constant. For example, the thickness of the exposed first conductive liner ESL1 may be less than the thickness of the first conductive liner ESL1 formed between the first conductive pattern ML1 and the second portion conductive pattern V1_P1′.

The second conductive pattern V1_P1 overlapping the first contact plug V0a may be removed by the CMP process, and the second conductive pattern V1_P1 overlapping the second contact plug V0b may be partially removed in the vertical direction to have the same level as a level of the upper surface of the exposed first conductive liner ESL1, such that the second portion conductive pattern V1_P1′ may be formed. In an example, the first conductive liner ESL1 overlapping the second contact plug V0b is not exposed and may be formed between the first conductive pattern ML1 and the second portion conductive pattern V1_P1′.

Referring to FIG. 12D, a third conductive pattern V1_P2 may be further deposited on the exposed first conductive liner ESL1 and the second portion conductive pattern V1_P1′, and a mask layer M may be formed on the third conductive pattern V1_P2. In an example, the upper surface of the exposed first conductive liner ESL1 and the upper surface of the second portion conductive pattern V1_P1′ may have the same level, such that the upper surface of the third conductive pattern V1_P2 formed on the exposed first conductive liner ESL1 and second portion conductive pattern V1_P1′ may also have a flat surface profile. The third conductive pattern V1_P2 may include the same material as a material of the second conductive pattern V1_P1. In an example, the third conductive pattern V1_P2 may include ruthenium (Ru).

Referring to FIG. 12E, a portion of the first conductive pattern ML1, the first conductive liner ESL1, the second portion conductive pattern V1_P1′, and the third conductive pattern V1_P2 may be removed using a mask layer M, such that a portion of the upper surface of the second lower insulating structure 191 may be exposed, and accordingly, the first conductor structure CS1_d may be formed on the first contact plug V0a and the second conductor structure CS2 may be formed on the second contact plug V0b. The mask layer M may be, for example, a hard mask layer.

Referring to FIG. 12F, the insulating material 192P may be applied to cover the first conductor structure CS1_d and the second conductor structure CS2 on the second lower insulating structure 191. Thereafter, referring to FIG. 4, by performing a CMP process throughout the entire region to expose the upper surface of the first via V1a_d of the first conductor structure CS1_d and the upper surface of the second via V1b of the second conductor structure CS2, the interlayer insulating layer 192 may be formed.

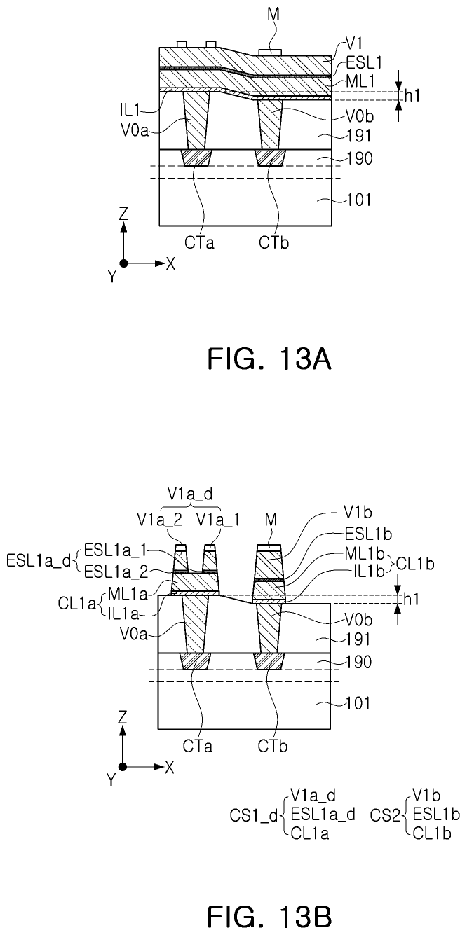

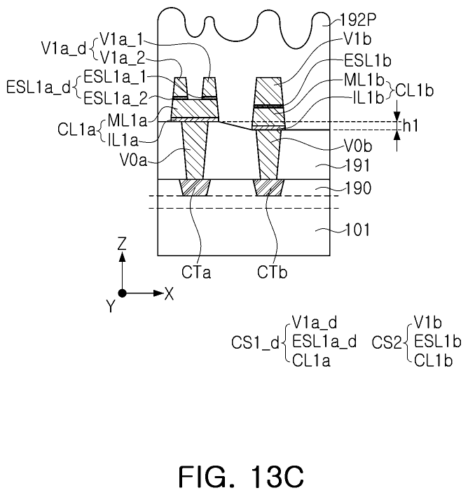

FIGS. 13A to 13C are diagrams illustrating a method of manufacturing the semiconductor device in FIG. 4 according to example embodiments.

Referring to FIG. 13A, as a subsequent process to FIG. 12B, the first conductive pattern ML1, the first conductive liner ESL1 and the second conductive pattern V1 may be deposited in order on the barrier layer IL1. The mask layer M may be formed on the second conductive pattern V1. The mask layer M may be formed on the upper surface of the second conductive pattern V1 overlapping the first contact plug V0a and on the upper surface of the second conductive pattern V1 overlapping the second contact plug V0b. In other words, the first portion of mask layer M disposed on the upper surface of the second conductive pattern V1 overlapping the first contact plug V0a may be formed at a level higher than a level of the second portion of the mask layer M disposed on the upper surface of the second conductive pattern V1 overlapping the second contact plug V0b.

Referring to FIG. 13B, a portion of the first conductive pattern ML1, the first conductive liner ESL1, and the second conductive pattern V1 may be removed using mask layer M, such that a portion of the upper surface of the second lower insulating structure 191 may be exposed, and accordingly, the first conductor structure CS1_d on the first contact plug V0a and the second conductor structure CS2 on the second contact plug V0b may be formed.

Referring to FIG. 13C, the insulating material 192P may be applied to cover the first conductor structure CS1_d and the second conductor structure CS2 on the second lower insulating structure 191. Thereafter, referring to FIG. 4, a CMP process may be performed across the entire region such that the upper surface of the first via V1a_d of the first conductor structure CS1_d and the upper surface of the second via V1b of the second conductor structure CS2 may be exposed, and accordingly, the interlayer insulating layer 192 may be formed.

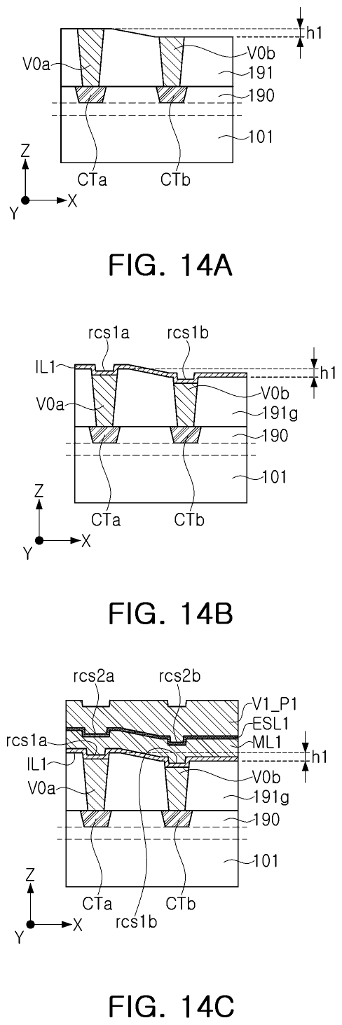

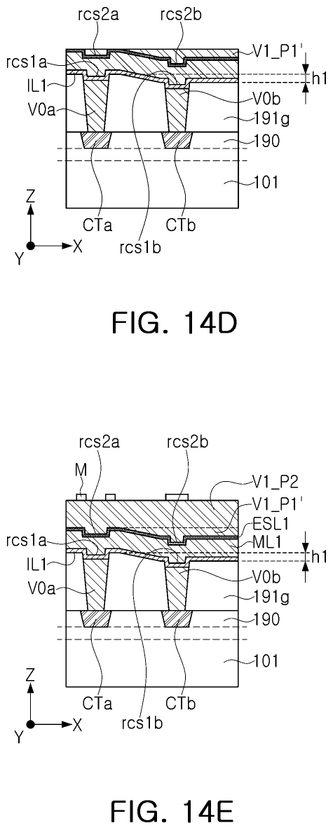

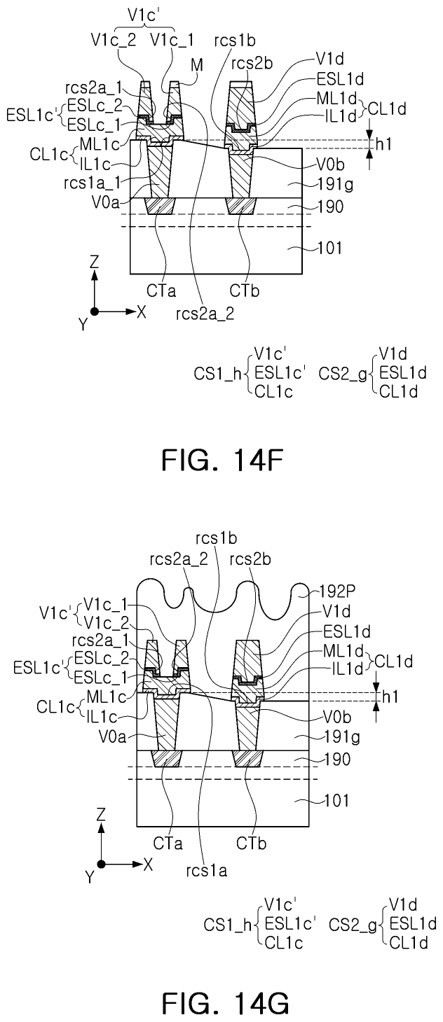

FIGS. 14A to 14G diagrams illustrating a method of manufacturing the semiconductor device in FIG. 8 according to example embodiments.

Referring to FIG. 14A, the method of manufacturing a semiconductor device may include forming the first lower insulating structure 190 on the substrate 101, forming the first and second contact structures CTa and CTb penetrating at least a portion of the first lower insulating structure 190, forming the second lower insulating structure 191 covering the first and second contact structures CTa and CTb, and forming the first and second contact plugs V0a and V0b penetrating the second lower insulating structure 191 and connected to the first and second contact structures CTa and CTb.

Referring to FIG. 14B, by removing a portion of the second lower insulating structure 191 and the first and second contact plugs V0a and V0b, a first lower insulating structure 191g including a first portion in which the upper surface of the second lower insulating structure 191 is exposed, and a second portion disposed at a level lower than a level of the first portion and exposing the upper surface of the first contact plug V0a and the upper surface of the second contact plug V0b may be formed. A barrier layer IL1 may be formed on the first lower insulating structure 191g. The barrier layer IL1 may be formed according to the surface profile of the upper surface of the first lower insulating structure 191g. The barrier layer IL1 may include a first protruding surface rcs1a protruding toward the upper surface of the first contact plug V0a and a second protruding surface rcs1b protruding toward the upper surface of the second contact plug V0b.

Referring to FIG. 14C, the first conductive pattern ML1, the first conductive liner ESL1, and the second conductive pattern V1_P1 may be formed in order on the barrier layer IL1. The first conductive pattern ML1, the first conductive liner ESL1, and the second conductive pattern V1_P1 may be formed according to the surface profile of the upper surface of the barrier layer IL1.

Referring to FIG. 14D, a CMP process may be performed on the second conductive pattern V1_P1 throughout the entire region such that a portion of the first conductive liner ESL1 disposed at the highest level among the first conductive liners ESL1 is exposed. Accordingly, the step difference due to the level difference between the upper surface of the first contact plug V0a and the upper surface of the second contact plug V0b may be reduced (or reduced). The second conductive pattern V1_P1 overlapping the first contact plug V0a may be removed by the CMP process, and the second conductive pattern V1_P1 overlapping the second contact plug V0b may be removed in the vertical direction to have the same level as the upper surface of the exposed first conductive liner ESL1 such that the second portion conductive pattern V1_P1′ may be formed. In an example, the first conductive liner ESL1 overlapping the second contact plug V0b may not be exposed and may be formed between the first conductive pattern ML1 and the second portion conductive pattern V1_P1′.

Referring to FIG. 14E, a third conductive pattern V1_P2 may be further formed on the exposed first conductive liner ESL1 and the second portion conductive pattern V1_P1′, and the mask layer M may be formed on the third conductive pattern V1_P2.

Referring to FIG. 14F, a portion of the first conductive pattern ML1, the first conductive liner ESL1, the second portion conductive pattern V1_P1′, and the third conductive pattern V1_P2 may be removed using the mask layer M, such that a portion of the upper surface of the second lower insulating structure 191 may be exposed, and accordingly, the first conductor structure CS1_h may be formed on the first contact plug V0a and the second conductor structure CS2_g may be formed on the second contact plug V0b.

Referring to FIG. 14G, the insulating material 192P may be applied to cover the first conductor structure CS1_h and the second conductor structure CS2_g on the second lower insulating structure 191. Thereafter, referring to FIG. 8, a CMP process may be performed throughout the entire region to expose the upper surface of the first via V1c′ of the first conductor structure CS1_h and the upper surface of the second via V1d of the second conductor structure CS2_g, thereby forming the interlayer insulating layer 192.

According to the aforementioned example embodiments, the semiconductor device may include contact plugs having upper surfaces disposed at different levels and conductor structures disposed on the contact plugs and having upper surfaces disposed at the same level. Accordingly, degradation of electrical reliability caused by step differences between the contact plugs may be addressed.

While the example embodiments have been illustrated and described above, it will be configured as apparent to those skilled in the art that modifications and variations could be made without departing from the scope of the inventive concept as defined by the appended claims.

What is claimed is:

1. A semiconductor device, comprising:
a first contact plug having a first upper surface and a second contact plug having a second upper surface disposed at a vertical level different from a vertical level of the first upper surface;
a first conductor structure disposed on the first contact plug and connected to an upper surface of the first contact plug;
a second conductor structure disposed on the second contact plug and connected to an upper surface of the second contact plug; and
an interlayer insulating layer on side surfaces of the first and second conductor structures,
wherein the first and second contact plugs include portions disposed at the same vertical level as one another,
wherein the first conductor structure includes:
a first interconnection line connected to the first upper surface of the first contact plug;
a first via on the first interconnection line; and
a first barrier layer between the first interconnection line and the first via,
wherein the second conductor structure includes:
a second interconnection line connected to the second upper surface of the second contact plug;
a second via on the second interconnection line; and
a second barrier layer between the second interconnection line and the second via,
wherein the first interconnection line, the first via, and the first barrier layer have first side surfaces which are aligned,
wherein the second interconnection line, the second via, and the second barrier layer have second side surfaces which are aligned, and
wherein the interlayer insulating layer is in contact with the first side surfaces of the first interconnection line, the first via, and the first barrier layer, and the second side surfaces of the second interconnection line, the second via, and the second barrier layer.

2. The semiconductor device of claim 1,
wherein the first interconnection line includes a first overlapping portion vertically overlapping the first via and a first non-overlapping portion not vertically overlapping the first via,
wherein the interlayer insulating layer covers an upper surface of the first non-overlapping portion of the first interconnection line, and
wherein the first barrier layer is disposed between an upper surface of the first overlapping portion of the first interconnection line and a lower surface of the first via.

3. The semiconductor device of claim 1, wherein the first and second conductor structures have inclined side surfaces such that a width thereof increases downwardly.

4. The semiconductor device of claim 1,
wherein a width of a lower region of the first via is greater than a width of an upper region of the first via, and
wherein a width of a lower region of the first interconnection line is greater than a width of an upper region of the first interconnection line.

5. The semiconductor device of claim 1,
wherein the first interconnection line includes a first overlapping portion vertically overlapping the first via and a first non-overlapping portion not vertically overlapping the first via,
wherein the second interconnection line includes a second overlapping portion vertically overlapping the second via and a second non-overlapping portion not vertically overlapping the second via, and
wherein a thickness of the first overlapping portion is the same as a thickness of the second overlapping portion.

6. The semiconductor device of claim 1,
wherein each of the first and second interconnection lines includes a conductive barrier layer and a conductive interconnection layer on the conductive barrier layer, and
wherein the conductive interconnection layer includes a material that is the same as a material of the first and second vias.

7. The semiconductor device of claim 1,
wherein the first and second interconnection lines and the first and second vias include ruthenium (Ru), and
wherein the first and second barrier layers include ruthenium nitride (RUN).

8. The semiconductor device of claim 1, wherein a thickness of the first barrier layer and a thickness of the second barrier layer are different than each other.

9. The semiconductor device of claim 1,
wherein an upper surface of the first contact plug is disposed at a vertical level higher than a vertical level of an upper surface of the second contact plug, and
wherein a thickness of the second barrier layer is greater than a thickness of the first barrier layer.

10. The semiconductor device of claim 9, wherein a vertical thickness of the first via is greater than a vertical thickness of the first interconnection line.

11. The semiconductor device of claim 1, wherein the first via includes a 1-1 via and a 1-2 via disposed on the first interconnection line and spaced apart from each other.

12. The semiconductor device of claim 1, further comprising:
a lower insulating structure on side surfaces of the first and second contact plugs,
wherein a lower surface of the first interconnection line includes a first portion on the lower insulating structure, and a second portion disposed at a vertical level lower than a vertical level of the first portion and in contact with a first upper surface of the first contact plug.

13. The semiconductor device of claim 1, wherein the first barrier layer includes a central portion and an edge portion extending from the central portion and disposed at a vertical level higher than a vertical level of the central portion.

14. The semiconductor device of claim 1, further comprising:
an upper conductive pattern in contact with the first via,
wherein the upper conductive pattern includes an upper conductive barrier layer and an upper conductive layer on the upper conductive barrier layer, and
wherein the upper conductive barrier layer is in contact with a lower surface of the upper conductive layer and a side surface of the upper conductive layer.

15. The semiconductor device of claim 14,
wherein the first interconnection line includes a first conductive barrier layer and a first conductive layer on the first conductive barrier layer, and
wherein the first conductive barrier layer is in contact with a lower surface of the first conductive layer and is not in contact with a side surface of the first conductive layer.

16. A semiconductor device, comprising:
an interconnection line including a first portion and a second portion;
a via on the first portion of the interconnection line;
a conductive barrier layer between a lower surface of the via and an upper surface of the first portion of the interconnection line; and
an interlayer insulating layer in contact with side surfaces of the interconnection line, the via, and the conductive barrier layer and covering the second portion of the interconnection line.

17. The semiconductor device of claim 16, wherein the interlayer insulating layer is in contact with an upper surface of the second portion of the interconnection line.

18. The semiconductor device of claim 16, wherein the conductive barrier layer extends from a portion disposed between a lower surface of the via and an upper surface of the first portion of the interconnection line to a region between the interlayer insulating layer and an upper surface of the second portion of the interconnection line.

19. A semiconductor device, comprising:
a first contact plug having a first upper surface and a second contact plug having a second upper surface disposed at a vertical level different than a vertical level of the first upper surface;
a first conductor structure disposed on the first contact plug and connected to an upper surface of the first contact plug;
a second conductor structure disposed on the second contact plug and connected to an upper surface of the second contact plug; and
an interlayer insulating layer on side surfaces of the first and second conductor structures,
wherein the first and second contact plugs include portions disposed at the same vertical level as one another,
wherein the first conductor structure includes:
a first interconnection line connected to the first upper surface of the first contact plug; and
a first via on the first interconnection line,
wherein the second conductor structure includes:
a second interconnection line connected to the second upper surface of the second contact plug and having an upper surface lower than an upper surface of the first interconnection line;
a second via on the second interconnection line; and
a barrier layer disposed between the second interconnection line and the second via,
wherein a vertical thickness of the first via is different from a vertical thickness of the second via.

20. The semiconductor device of claim 19, wherein an upper surface of the first via and an upper surface of the second via are disposed at the same vertical level as one another.
